(19) United States
(12) Patent Application Publication
(10) Pub. No.: US 2026/0327846 A1
(43) Pub. Date: Oct. 22, 2026

(54) METHOD, APPARATUS, SYSTEM AND COMPUTER STORAGE MEDIUM OF CONTROLLING CRYSTAL GROWTH

(71) Applicant: Zing Semiconductor Corporation, Shanghai (CN)

(72) Inventor: Weimin SHEN, Shanghai (CN)

(73) Assignee: Zing Semiconductor Corporation, Shanghai (CN)

(21) Appl. No.: 19/722,857

(22) Filed: Jun. 28, 2026

Related U.S. Application Data
(62) Division of application No. 18/397,872, filed on Dec. 27, 2023.

(30) Foreign Application Priority Data
Dec. 30, 2022 (CN) 202211722191.3

(51) Int. Cl. C30B 15/20

(52) U.S. Cl. CPC C30B 15/206

(57) ABSTRACT

The present invention discloses a method, apparatus, system and computer storage medium of controlling crystal growth. The method may comprise: obtaining a target piecewise curve of a heater power at different crystal lengths, a segment dividing point being positioned at an intersection point of adjacent segments of the target piecewise curve; based on the crystal lengths, interpolation calculating a value of the heater power at a length as a control value of the heater power; based on the control value of the heater power at different crystal lengths, obtaining a target control curve of the heater power, the target control curve of the heater power being smooth at the segment dividing point.

### FIELD OF THE INVENTION

The present invention generally relates to a technical field of crystal growth, and specifically, relates to a method, an apparatus and a computer storage medium of controlling crystal growth.

### BACKGROUND OF THE INVENTION

As prosperity of integrated circuit industry arises, manufactures of IC devices are drawn to more critical requirements for single-crystal silicon materials, such as those having a great diameter, which is an essential material of substrate to make IC devices. Czochralski method, a main method to growth monocrystalline silicon, heats the polysilicon in a crucible and dips a seed on a surface of the melt then pull up the seed to growth crystal. Under a controlled condition, at an interface between the crystal and the melt to solidify and grow the single crystal along with decreasing of the temperature.

During manufacturing a single-crystal silicon, a necking process is performed after dipping the crystal seed into a silicon melt to grow a section of free dislocation crystal with a small diameter. Afterwards, a process called crown growth is performed to enlarge the diameter of the crystal to a target diameter. Then, a process to keep required diameter called body process is performed to grow the main section of crystal. In this step, not only the diameter of the crystal should be controlled within a certain range, but also a pulling speed should be controlled within a predetermined range. If fluctuation of diameter causing the diameter deviates from the target occurs, as shown in FIG. 3, the fluctuation of diameter will cause fluctuation of pulling speed. When fluctuation of pulling speed exceeds the predetermined range, defects of COP (Crystal Originated Particle) related to holes or A-defect related to dislocations will occur to deteriorate yield of silicon wafer.

As such, the present invention provides a method, an apparatus and a computer storage medium of controlling crystal growth to solve aforesaid problems.

### SUMMARY OF THE INVENTION

A series of simplified idea which will be detailed in several embodiments are introduced in this section. Please note that what is disclosed in summary of the invention is not intended to limit key or essential features of subject matters to be protected by the present invention, nor try to confirm claimed scope of the subject matters.

One aspect of the present invention is to provide a method of controlling crystal growth, comprising: obtaining a sectional target curve of heater power at different crystal lengths, the sectional target curve comprising at least one joint point which is an intersection point of two adjacent sections of the sectional target curve; based on one of the crystal lengths, obtaining a calculated heater power at the one of the crystal lengths by interpolation calculation, to be used as a controlling value of heater power at the one of the crystal lengths; and based on the controlling value of heater power at the crystal lengths, obtaining a target controlling curve, which is smooth at the joint point.

Optionally, the step of obtaining a calculated heater power at the one of the crystal lengths by interpolation calculation may comprise perform interpolation calculation of quadratic spline curve to obtain the calculated heater power at the one of the crystal lengths.

Optionally, the step of obtaining a calculated heater power at the one of the crystal lengths by interpolation calculation may comprise perform interpolation calculation of B-spline curve to obtain the calculated heater power at the one of the crystal lengths.

Optionally, the step of obtaining a sectional target curve of heater power at different crystal lengths may comprise analyzing historical data of crystal growth to repeat iteration until obtaining the sectional target curve of heater power at different crystal lengths.

Optionally, the step of obtaining a target controlling curve which is smooth at the joint point may comprise obtaining the target controlling curve a first derivative of which is continuous before and after the joint point, and a slope of which is the first derivative.

Optionally, after the step of obtaining a calculated heater power at the one of the crystal lengths to be used as a controlling value of heater power at the one of the crystal lengths, a step of based on a deviation of crystal diameter, compensating a deviation of heater power may be comprised.

Optionally, a section number of sectional target curve of heater power may be within 30 to 100 sections.

Another aspect of the present invention is to provide an apparatus of controlling crystal growth, comprising: a sectional target curve obtaining module, for obtaining a sectional target curve of heater power at different crystal lengths, the sectional target curve comprising at least one joint point which is an intersection point of two adjacent sections of the sectional target curve; an interpolation calculating module, for obtaining a calculated heater power at the one of the crystal lengths by interpolation calculation based on one of the crystal lengths, to be used as a controlling value of heater power at the one of the crystal lengths; and a target controlling curve obtaining module, for obtaining a target controlling curve, which is smooth at the joint point, based on the controlling value of heater power at the crystal lengths.

Yet, another aspect of the present invention is to provide a system of controlling crystal growth, comprising: a memory, a processor, and a computer program stored in the memory for execution by the processor, wherein the processor executes the computer program to perform the steps of one of aforesaid methods of controlling crystal growth.

Yet, another aspect of the present invention is to provide a computer storage medium, on which a computer program is stored, and the computer program is executed to perform the steps of one of aforesaid methods of controlling crystal growth.

According to one of the method, apparatus and computer storage medium of controlling crystal growth of the present invention, the smooth target controlling curve of heater power may be obtained by interpolation calculation based on the sectional target curve of heater power to decrease fluctuation of diameter and pulling speed during crystal growth, reduce possibility of intrinsic defects in the grown crystal, and improve yield of silicon wafer products.

### BRIEF DESCRIPTION OF THE DRAWINGS

Various objects and advantages of the present invention will be more readily understood from the following detailed description when read in conjunction with the appended drawing, in which:

FIG. 1 shows a perspective view of a crystal grower used in a method of controlling crystal growth according to an embodiment of the present invention;

FIG. 2 shows a main flow chart of a method of controlling crystal growth according to an embodiment of the present invention;

FIG. 3 shows a perspective view of a fluctuation of crystal diameter;

FIG. 4 shows a perspective view of a sectional target curve of heater power at different crystal lengths according to an embodiment of the present invention;

FIG. 5 shows a perspective view of a target controlling curve of heater power obtained by interpolation calculation of quadratic spline curve according to an embodiment of the present invention;

FIG. 6 shows a perspective view of a target controlling curve of heater power obtained by interpolation calculation of B-spline curve according to an embodiment of the present invention;

FIG. 7 shows a block diagram of an apparatus of controlling crystal growth according to an embodiment of the present invention;

FIG. 8 shows a perspective view of a system of controlling crystal growth according to an embodiment of the present invention.

### DESCRIPTION OF EMBODIMENTS OF THE INVENTION

Reference is now made to the following examples taken in conjunction with the accompanying drawings to illustrate implementation of a method of controlling crystal growth of the present invention. As evident to those with ordinary skill in the art, the present invention may be implemented without one or more details illustrated here. In some examples, some feature belonging to common knowledge in the art may be skipped to avoid from confusion with the present invention.

Great details are provided here so that this disclosure will be thorough, and will fully understand the present application to a person skilled in the art. Apparently, implementing the present invention is not limited to those details known by the person skilled in the art. In addition to the detailed description described below, the present invention also may be implemented in other ways.

Please note that the terms of “comprise” and/or “consist of” are used to indicate existence of at least one feature, object, step, operation, element and/or component without excluding existence of one or more other feature, object, step, operation, element, component and/or a combination thereof.

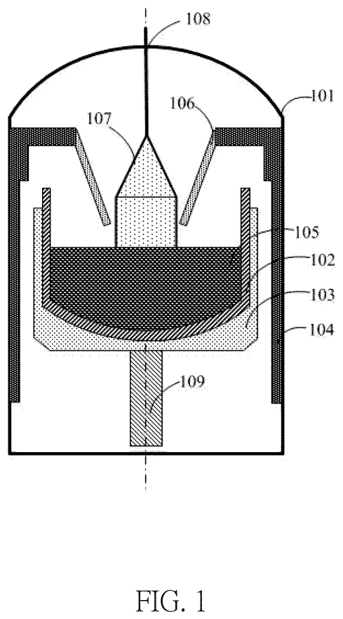

FIG. 1 shows a perspective view of a crystal grower used in a method of controlling crystal growth according to an embodiment of the present invention. As shown in FIG. 1, a crystal grower is used to grow a single-crystal silicon with Czochralski method. The crystal grower may comprise a furnace body 101 positioned with a heating apparatus and a pulling mechanism. The heating apparatus may comprise a quartz crucible 102, a graphite crucible 103 and a heater 104. The quartz crucible 102 may be used to receive a silicon raw material, such as polysilicon. The silicon raw material may be heated to melt 105. The graphite crucible 103 wraps the quartz crucible 102 and supports the quartz crucible 102 during the heating process. The heater 104 is positioned outside the graphite crucible 103. A reflector 106, positioned above the quartz crucible 102, may have an inverted truncated cone shape blocking heat radiation from the heater 104 and the silicon melt 105 to single crystal silicon ingot 107, so to keep a temperature gradient of the single crystal silicon ingot 107. Namely, the reflector 106 may be used to focus the air blown down along the reflector 106 to a vicinity of a growing interface, so as to enhance heat dissipation of the single crystal silicon ingot 107. A heat preservation material, such as carbon felt, may be positioned on a sidewall of the furnace body 101.

The pulling mechanism may comprise an upright crystal seed shaft 108 and a crucible shaft 109. The crystal seed shaft 108 is positioned above the quartz crucible 102, and the crucible shaft 109 is positioned at the bottom of the graphite crucible 103. A crystal seed is positioned at the bottom of the crystal seed shaft 108 with a clamp, and a driving mechanism is connected with the top of the crystal seed shaft 108 to rotate and pull the crystal seed shaft 108 up upward slowly. A crucible axes driving mechanism is positioned at the bottom of the crucible axes 109 to enable the crucible shaft 109 to rotate the quartz crucible 102.

When growing the single crystal, at first, the polysilicon is put into the quartz crucible 102. Then, the crystal grower is closed and vacuumed, and a protecting gas is introduced into the crystal grower. For example, the protecting gas may be argon air, a purity of which is greater than 99.9 %, gas pressure of which is within 5 mbar to 100 mbar, and flow rate of which is within 70 slpm to 200 slpm. Then, the heater 104 may be turned on to heat the polysilicon, a melt point of which may be 1420 °C, until it is melted to turn to the silicon melt 105.

The crystal seed is then dipped into the silicon melt 105. Driven by the crystal seed 108, the crystal seed rotates and meanwhile is pulled up to grow the single crystal silicon ingot 107. The crystal seed may be a cut or drilled piece of single crystal silicon in which crystal lattices are aligned with a certain lattice direction, such as <100>, <111>, <110>, etc. The crystal seeds may be in a cylinder shape typically. The single crystal silicon ingot 107 may be grown with several sequential steps comprising a neck step, a crown step, a body step and a tail step.

Specifically, at first, the neck step is performed. In this step, after the silicon melt is stable at a certain temperature, the seed is dipped into the silicon melt and then pulled up at a certain speed to grow a fine neck having a certain diameter until a length of the fine neck reaches a predetermined length. The main effect to perform the neck step is eliminating dislocation defects in the single crystal silicon caused by thermal shock. Super cooled crystal frontier may be used to drive and arrange silicon atoms in order on a silicon solid at a solid-liquid interface to form the single crystal silicon. For example, the pulling speed may be within 1.0 mm/min to 6.0 m/min, the length of the fine neck may be 0.6-1.4 times of a ingot diameter, and the diameter of the fine neck may be within 5 to 7 mm.

Then, the crown growth step may be performed. In this step, after the fine neck reaches the predetermined length, the pulling speed as well as the temperature of the silicon melt may be decreased. Decreased temperature will facilitate horizontal growth of the single crystal silicon. Therefore, a diameter of the single crystal silicon will be increased. This step is also called shoulder step because a section of shoulder of the ingot having a truncated cone shape is formed in this step.

Then, the shouldering step is performed. When the diameter of the single crystal silicon is enlarged to a target diameter, with raising a heating power of the heater 104 to increase the temperature of the silicon melt, and adjusting the pulling speed to pull up the crystal seed, a rotation speed of the crystal seed and a rotation speed of the quartz crucible 102, etc., the horizontal growth of the single crystal silicon may be inhibited but a vertical growth of the single crystal silicon may be facilitated. As such, the single crystal silicon may be grown almost isometrically.

Then, the body step may be performed after the diameter of the single crystal silicon ingot reaches a predetermined value. In this step, a section of ingot having an isometric diameter, called body of the ingot, may be formed. Specifically, the temperature of the quartz crucible 102, the pulling speed, the rotation speed of the quartz crucible 102 and the rotation speed of the ingot may be adjusted to stable the growing speed of the ingot and keep the diameter of the ingot unchanged until the tail step. The body step is the main step of crystal growth which may take dozens of hours which may be over one hundred hours.

Finally, the tail step may be performed. At this step, the pulling speed is increased fast and the temperature of the silicon melt 105 is increased at the same time to reduce the diameter of the ingot, so as to form a conic section. When a tip of the conic section is small enough, the conic section eventually leaves the liquid surface. Before using the produced ingot, it is pulled up to an upper chamber to cool for a while. At this time, a growth period has been ended.

On a lid of the crystal grower, a CCD diameter measuring apparatus measuring the diameter of the crystal is positioned. A sensor inside the pulling mechanism may measure the length X of the crystal. The length X and the diameter D of the crystal may be feedbacked to a control center of crystal growth (PLC/PC) for controlling the crystal growth by adjusting a power P of the heater (or a temperature of the heater) and the pulling speed V of the crystal.

In the aforesaid steps of crystal growth, the body step is crucial because it requires for controlling the crystal diameter within a constant range and limiting the pulling speed in an indicated range. If the diameter deviated from a target occurs, which means a fluctuation of diameter shows, as shown in FIG. 3, the fluctuation of diameter will lead to fluctuation of pulling speed. When the pulling speed exceeds a certain range of a target pulling speed, defects of COP (Crystal Originated Particle) related to holes or A-defect related to dislocations will occur to deteriorate yield of silicon wafer.

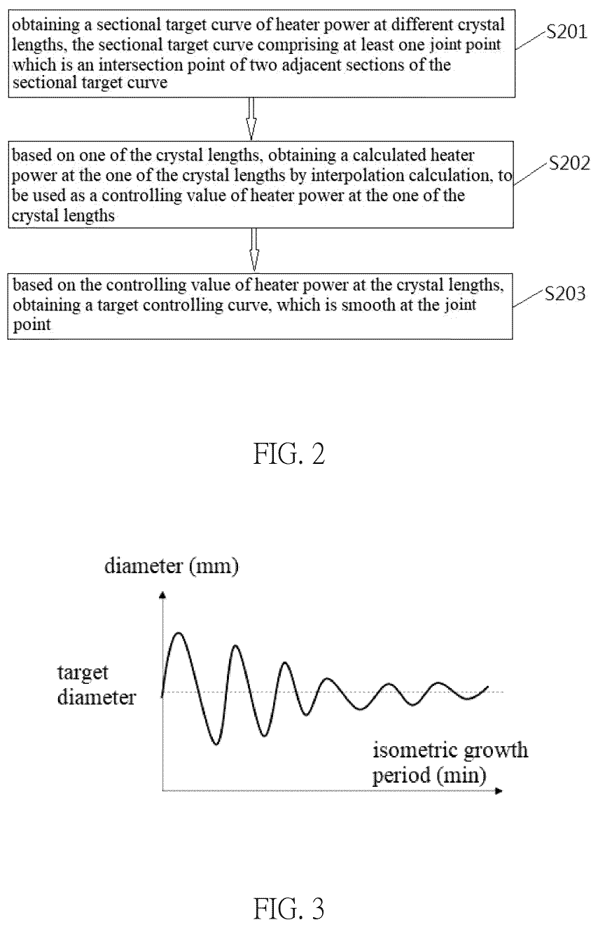

In light of aforesaid problem, the present invention provides a method of controlling crystal growth, as shown in FIG. 2, comprising: a step S201: obtaining a sectional target curve of heater power at different crystal lengths, the sectional target curve comprising at least one joint point which is an intersection point of two adjacent sections of the sectional target curve; a step S202: based on one of the crystal lengths, obtaining a calculated heater power at the one of the crystal lengths by interpolation calculation, to be used as a controlling value of heater power at the one of the crystal lengths; and a step S203: based on the controlling value of heater power at the crystal lengths, obtaining a target controlling curve, which is smooth at the joint point.

Exemplarily, the step S201 of obtaining a sectional target curve of heater power at different crystal lengths comprises analyzing historical data of crystal growth to repeat iteration until obtaining the sectional target curve of heater power at different crystal lengths.

Crystal growth may be controlled by both inter-batch or in-situ technologies. Feed-forward model implements a guide of controlling with designed target values of diameter, pulling speed and heater power (or a temperature of the heater) according to the historical data of crystal growth. Real-time feedback may be applied to a closed-loop PID (Proportional-Integral-Derivative) controlling mechanism according to the data collected by real-time monitoring the growing crystal diameter to control deviation of diameter and pulling speed of crystal.

Further, the historical data of crystal growth may comprise the data of crystal growth consolidated from a plurality of previous batches. Specifically, during the crystal growth, thermal environment and location condition in the apparatus of crystal growth gradually change along with the length variation of the crystal growth. The changes may comprise crystal length X, volume of the silicon melt V and position of the crucible receiving the silicon melt. With these changes, it is needed to change the heater power correspondingly to stabilize crystal growing speed at the interface of crystal growth.

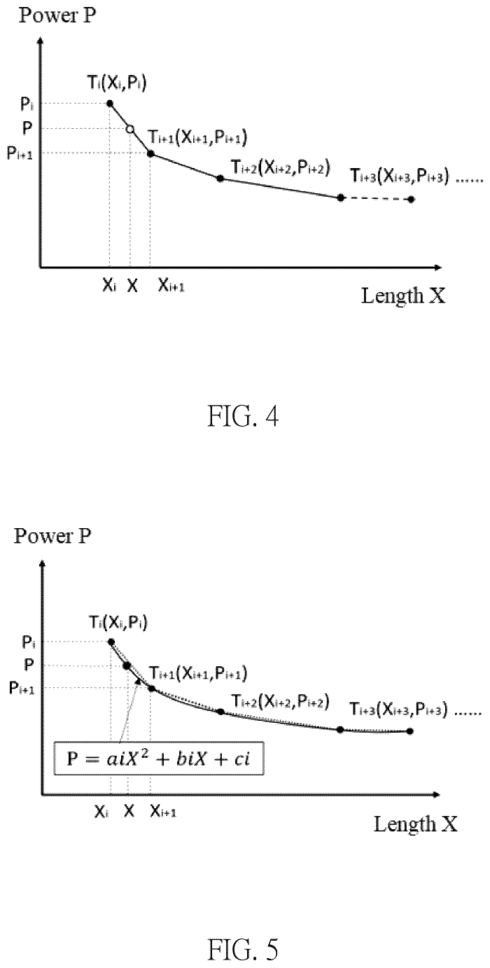

In an embodiment, historical data of crystal growth may be analyzed and iteration may be repeated until obtaining the sectional target curve of heater power at different crystal lengths, as shown in FIG. 4.

Please note that although only several sections are shown in FIG. 4, a section number of sectional target curve of heater power may be varied, and typically, the section number of sectional target curve of heater power may be within 30 to 100 sections.

After obtaining aforesaid sectional target curve of heater power, if linear interpolation calculation is performed to calculate the heater power at the corresponding crystal length, as shown in FIG. 4, the resulting target controlling curve of heater power will be totally the same as aforesaid target controlling curve of heater power. Apparently, such target controlling curve of heater power is not smooth, because increment or decrement of power is relatively great when the crystal length passing through the joint point. Specifically, right before or after the joint point, such as Tᵢ₊₁, the slope of the target controlling curve of heater power changes greatly (from the slope of the Ti−Tᵢ₊₁ section to the slope of the Tᵢ₊₁−Tᵢ₊₂ section). Such change causes corresponding change of the variation rate of the output heat from the heater inside the apparatus. Accumulated along with the crystal growth, small deviation of power change causing changed crystal growing rate at the interface of crystal growth will eventually lead to deviation of crystal diameter and pulling rate from the target values.

To make the target controlling curve of heater power smooth at the joint point, in another embodiment, the step of obtaining the calculated heater power at the one of the crystal lengths by interpolation calculation may comprise performing interpolation calculation of bi-quadratic spline curve to obtain the calculated heater power at the one of the crystal lengths, as shown in FIG. 5. Further, after obtaining the controlling value of heater power, another step of based on a deviation of crystal diameter, compensating a deviation of heater power may be performed.

Specifically, interpolation calculation of quadratic spline curve, rather than linear interpolation calculation, may be performed. Function of the quadratic spline curve may be: P=aiX²+biX²+ci. According to the interpolation calculation of quadratic spline curve, parameters of the curve (ai, bi, ci) may be calculated according to coordinates of joint points (i) and (i+1) and a slope of end points. Through keeping calculating sections of the quadratic spline curve and performing interpolation calculation, the target controlling curve of heater power which is smooth at the joint points may be obtained. As such, a first derivative of the target controlling curve of heater power is continuous before and after the joint points, so as to ensure the variation of power is continuous and stable to meet required heat change in the crystal grower. Please note that first derivative of the target controlling curve of heater power is slope of the target controlling curve.

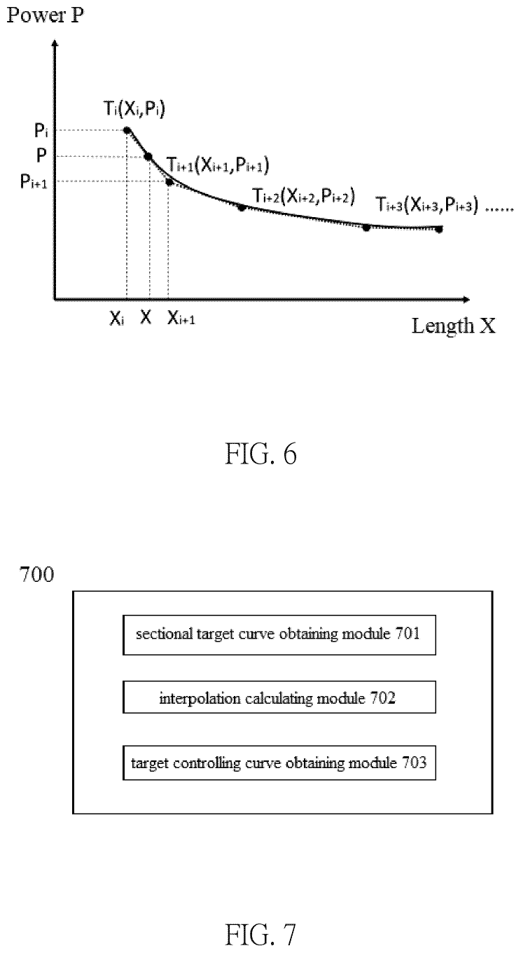

To make the target controlling curve of heater power smooth at the joint point, in another embodiment, the step of obtaining the calculated heater power at the one of the crystal lengths by interpolation calculation may comprise performing interpolation calculation of B-spline curve to obtain the calculated heater power at the one of the crystal lengths, as shown in FIG. 6.

Similarly, the interpolation calculation may be of B-spline curve, i.e. Bezier spline curve. Likewise, with such interpolation calculation of B-spline curve, the target controlling curve of heater power which is smooth at the joint point may be derived. As such, a first derivative of the target controlling curve is continuous before and after the joint point, and slope of the target controlling curve is the first derivative, so as to ensure the variation of power is continuous and stable to meet required heat change in the crystal grower.

In an embodiments of the present invention, with interpolation calculation of quadratic spline curve or B-spline curve, the target controlling curve of heater power, smooth at the joint point, may be used to control the power of the heater. Compared with another controlling mechanism which controls the power of the heater with another target controlling curve of heater power derived by linear interpolation calculation, maximum fluctuation rate of crystal diameter of the present invention is obviously decreased. The maximum fluctuation rate of crystal diameter is used to represent a ratio of deviation of maximum or minimum crystal diameter relative to a target diameter to the target diameter. Specifically, the maximum fluctuation rate in a head of the crystal may be decreased to ±0.5% from ±2%, the maximum fluctuation rate in a body of the crystal may be decreased to ±0.1% from ±0.3%, and maximum fluctuation rate in an end of the crystal may be decreased to ±0.2% from ±0.6%. Further, the decreased the maximum fluctuation rate promotes the yield of the crystal, and specifically, an average yield of crystal may be increased to 90% from 80%.

According to the method of controlling crystal growth according to the present invention, interpolation calculation may be performed on the basis of the sectional target curve of heater power to obtain the smooth target controlling curve of heater power, reduce the fluctuation of diameter and pulling speed of crystal growth, reduce possibility of intrinsic defects, and promote yield of silicon wafer product.

As shown in FIG. 7, an apparatus of controlling crystal growth 700 according to an embodiment of the present invention may comprise a sectional target curve obtaining module 701, an interpolation calculating module 702 and a target controlling curve obtaining module 703.

The sectional target curve obtaining module 701 may be used to obtain the sectional target curve of heater power at different crystal lengths. The sectional target curve at least comprise a first length section, a second length section and a joint point which is an intersection point of the first length section and the second length section. The interpolation calculating module 702 may be used to obtain a calculated heater power at the one of the crystal lengths by interpolation calculation based on one of the crystal lengths. The calculated heater power then may be used as a controlling value of heater power at the one of the crystal lengths. The target controlling curve obtaining module 703 may be used to obtain a target controlling curve based on the controlling value of heater power at the crystal lengths. The target controlling curve is smooth at the joint point.

Optionally, the step of obtaining a calculated heater power at the one of the crystal lengths by interpolation calculation may comprise perform interpolation calculation of bi-quadratic spline curve to obtain the calculated heater power at the one of the crystal lengths; the step of obtaining a calculated heater power at the one of the crystal lengths by interpolation calculation may comprise perform interpolation calculation of B-spline curve to obtain the calculated heater power at the one of the crystal lengths; the step of obtaining a sectional target curve of heater power at different crystal lengths may comprise analyzing historical data of crystal growth, and repeating iteration until obtaining the sectional target curve of heater power at different crystal lengths; the step of obtaining a target controlling curve which is smooth at the joint point may comprise obtaining the target controlling curve a first derivative of which is continuous before and after the joint point, and a slope of which is the first derivative; after the step of obtaining a calculated heater power at the one of the crystal lengths to be used as a controlling value of heater power at the one of the crystal lengths, a step of based on a deviation of crystal diameter, compensating a deviation of heater power may be comprised; and a section number of sectional target curve of heater power may be within 30 to 100 sections.

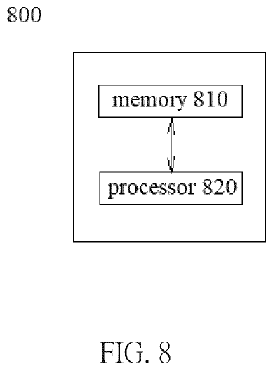

FIG. 8 shows a perspective view of a system of controlling crystal growth 800 according to an embodiment of the present invention. The system of controlling crystal growth 800 comprises a memory 810 and a processor 820.

The memory 810 may store a program coding implementing corresponding steps of the method of controlling crystal growth according to an embodiment of the present invention.

The processor 820 may be operated to execute the program coding stored in the memory 810 to perform corresponding steps of the method of controlling crystal growth according to an embodiment of the present invention, and implement a sectional target curve obtaining module 701, an interpolation calculating module 702 and a target controlling curve obtaining module 703 of an apparatus of controlling crystal growth according to an embodiment of the present invention.

In an embodiment, the program coding may be executed by the processor 820 to perform one of the methods of controlling crystal growth as mentioned above.

Further, according to an embodiment of the present invention, a computer storage medium may be provided to store program instructions which may be executed by a computer or processor to perform corresponding steps of the method of controlling crystal growth according to an embodiment of the present invention and implement corresponding modules of an apparatus of controlling crystal growth according to an embodiment of the present invention. The computer storage medium may comprise but not limited to a storage apparatus, a hard disc of a personal computer, a read-only memory (ROM), an erasable programmable read-only memory (EPROM), a compact disc read-only memory (CD-ROM), a USB memory and a combination thereof, such as a computer storage medium comprising a computer-readable program coding which generates a real-time command sequence, a computer storage medium comprising a computer-readable program coding which controls crystal growth, etc.

In an embodiment, the computer storage medium may be executed by a computer to implement each functional module of the apparatus of controlling crystal growth and/or perform a method of controlling crystal growth according to an embodiment of the present invention.

In an embodiment, the computer storage medium may be executed by a computer to perform one of the method of controlling crystal growth as mentioned above.

It is to be understood that these embodiments are not meant as limitations of the invention but merely exemplary descriptions of the invention with regard to certain specific embodiments. Those ordinarily skilled in the art may understand that, in addition to the detailed description, various modification and variants according to the present invention may be derived from the details disclosed here without departing from the merits of the invention. Depends on annexed claims and their equivalents, scope protected by the present invention is determined.

What is claimed is:

1. An apparatus of controlling crystal growth, comprising:
a sectional target curve obtaining module, for obtaining a sectional target curve of heater power at different crystal lengths, the sectional target curve comprising at least one joint point which is an intersection point of two adjacent sections of the sectional target curve;
an interpolation calculating module, for obtaining a calculated heater power at the one of the crystal lengths by interpolation calculation based on one of the crystal lengths, to be used as a controlling value of heater power at the one of the crystal lengths; and
a target controlling curve obtaining module, for obtaining a target controlling curve, which is smooth at the joint point, based on the controlling value of heater power at the crystal lengths.

2. A system of controlling crystal growth, comprising a memory, a processor, and a computer program stored in the memory for execution by the processor, wherein the processor executes the computer program to perform the steps of the method of controlling crystal growth according to claim 1.

3. A computer storage medium, on which a computer program is stored, wherein the computer program is executed to perform the steps of the method of controlling crystal growth according to claim 1.
